(19) United States
(12) Patent Application Publication
(10) Pub. No.: US 2025/0174452 A1
(43) Pub. Date: May 29, 2025

(54) RESIDUAL GAS ANALYSER, PROJECTION EXPOSURE APPARATUS COMPRISING A RESIDUAL GAS ANALYSER AND METHOD OF RESIDUAL GAS ANALYSIS

(71) Applicant: Carl Zeiss SMT GmbH, Oberkochen (DE)

(72) Inventors: Achim SCHOELL, Kitzingen (DE); Thorsten BENTER, Haan (DE); Hendrik KERSTEN, Wuppertal (DE); Kai KROLL, Wuppertal (DE); Marco THINIUS, Wuppertal (DE)

(21) Appl. No.: 19/027,800

(22) Filed: Jan. 17, 2025

Related U.S. Application Data
(63) Continuation of application No. PCT/EP2023/067054, filed on Jun. 22, 2023.

(30) Foreign Application Priority Data
Jul. 18, 2022 (DE) 10 2022 207 285.5

(51) Int. Cl. H01J 49/44; G03F 7/00; H01J 49/00; H01J 49/04; H01J 49/40

(52) U.S. Cl. CPC H01J 49/446; G03F 7/70225; G03F 7/7085; G03F 7/70883; H01J 49/0031; H01J 49/0422; H01J 49/403

(57) ABSTRACT

The disclosed techniques relate to a residual gas analyzer, in particular for analyzing a residual gas in an EUB projection exposure apparatus, including a mass spectrometer and an admission device for admitting ionized constituents of the residual gas from a vacuum environment into the mass spectrometer. The admission device includes an ion decelerator, with the ion decelerator having an adjustable deceleration voltage in order to subject the ionized constituents to selection with respect to kinetic energy before being transferred into the mass spectrometer. The disclosed techniques also relate to a projection exposure apparatus including such a residual gas analyzer, and a method for residual gas analysis.

### CROSS-REFERENCE TO RELATED APPLICATION

This is a Continuation of International Application PCT/EP2023/067054, which has an international filing date of Jun. 22, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Applications DE 10 2022 207 285.5 filed on Jul. 18, 2022.

### FIELD

The techniques disclosed herein relate to a residual gas analyzer, especially for analyzing a residual gas in a microlithography projection exposure apparatus. The disclosed techniques also relate to a projection exposure apparatus having a residual gas analyzer and to a method of residual gas analysis.

### BACKGROUND

Microlithography projection exposure apparatuses are utilized for the production of integrated circuits with particularly small structures. A mask (i.e., a reticle) exposed to very short-wave deep ultraviolet or extreme ultraviolet radiation (DUV or EUV radiation, referred to herein collectively as “very short-wave UV radiation”) is imaged onto a lithography object in order to transfer the mask structure to the lithography object.

The projection exposure apparatus includes multiple mirrors from which the radiation is reflected. The mirrors have a precisely defined shape and are precisely positioned such that the imaging of the mask onto the lithography object is of sufficient quality.

Because of the low transmittance of all gases for very short-wave UV radiation, the optical elements of such a projection exposure apparatus are operated in a vacuum environment. Interaction of the very short-wave UV radiation with the residual gas in the vacuum environment in the course of operation of the projection exposure apparatus gives rise to ionic, free-radical or neutral (excited) constituents of the residual gas. Knowledge of the composition of this gas or plasma atmosphere is important for the operation of the projection exposure apparatus. If the composition of the residual gas specified in the design of the apparatus is not observed, this can result in degradation effects on the mirrors of the projection exposure apparatus.

Inter alia, the degradation effects are based on the fact that some of the residual gas present in the apparatus is firstly ionized and secondly provided with a certain amount of kinetic energy. When such particles are incident on the surface of an optical element, degradation effects set in as a result of the combination of mechanical impact and great reactivity. State-of-the-art residual gas analyzers are not capable of energy-resolved and mass-resolved detection of such ionized constituents of the residual gas.

### SUMMARY

It is an object of the disclosed techniques to present a residual gas analyzer, a projection exposure apparatus, and a method of residual gas analysis that avoid these disadvantages.

The disclosed techniques relate to a residual gas analyzer, especially for analyzing a residual gas in a microlithography projection exposure apparatus. The residual gas analyzer includes a mass spectrometer and admission equipment for admission of ionized constituents of the residual gas into the mass spectrometer from a vacuum environment. The admission equipment includes an ion decelerator. The ion decelerator has an adjustable deceleration voltage.

By virtue of the ions being exposed to a deceleration voltage prior to the transfer into the mass spectrometer, the ions can be subjected to a selection according to kinetic energy. Only ions whose kinetic energy is sufficient to overcome the deceleration voltage reach the mass spectrometer and contribute to the analysis result.

The ion decelerator can include a deceleration path that is arranged between an inlet opening and an outlet opening of the ion decelerator. An electric potential that differs from the electric potential at the outlet end can be applied to the inlet end of the deceleration path so that the ions are decelerated by the potential difference. The potential difference corresponds to the deceleration voltage. The deceleration voltage can be set by modifying the potential difference.

The electric potential at the inlet end may have a fixed value. In particular, the electric potential at the inlet end may correspond to the electric potential of a housing of the vacuum environment, i.e., of the housing from which the residual gas is taken. The electric potential at the outlet end of the deceleration path may be adjustable in order to modify the deceleration voltage and hence the deceleration force acting on the ions. The electric potential at the outlet end may be positive in relation to the potential at the inlet end such that positively charged ions are repelled.

An intermediate electric potential may be formed between the inlet end and the outlet end of the deceleration path. The intermediate electric potential can be negative in relation to the potential at the inlet end such that free electrons are filtered out and prevented from passing the ion decelerator.

In one embodiment, the potentials of the ion decelerator are formed by grids, to which a voltage is applied. The ion decelerator may have a longitudinal direction that corresponds to the direction of movement of the ions. The grids can be aligned transversely to the longitudinal direction such that the ions pass through the grids on their way between the inlet end and the outlet end. The voltage applied to at least one of the grids may be modified in order to set the deceleration voltage. The potential of the first grid at the inlet end of the deceleration path preferably remains unchanged.

The ion decelerator can be traversed only by those ions whose kinetic energy is high enough not to be completely consumed by the deceleration voltage. The ionized constituents emerge from the ion decelerator at a speed that corresponds to the excess of kinetic energy.

It is advantageous for the mass spectrometry analysis if the ionized constituents have a defined state on entry into the mass spectrometer. The admission equipment of the residual gas analyzer may include an ion transfer device arranged between the ion decelerator and the mass spectrometer. The ion transfer device may be designed to guide the ionized constituents onward to the mass spectrometer without said ionized constituents being neutralized as a result of contact with component parts of the residual gas analyzer.

The ion transfer device may be configured such that the ions are guided through the ion transfer device in the longitudinal direction. The longitudinal direction of the ion transfer device may correspond to the longitudinal direction of the ion decelerator.

The ion transfer device may include a pole arrangement composed of multiple electric poles. An alternating electric field may be applied to the poles, in order to steer the ionized constituents onto a path in the longitudinal direction of the ion transfer device. Each pole may be arranged between two adjacent poles of opposite electric potential. An RF voltage may be applied to the poles, i.e., an AC voltage in the radiofrequency range. In this way, the pole arrangement may act as ion optics, via which the ionized constituents of the residual gas are guided from an inlet end to an outlet end of the ion transfer device.

The pole arrangement may take the form of a hexapole. The hexapole may extend in the longitudinal direction of the ion transfer device and include six electric poles that are distributed over the circumference of the ion transfer device. The ion transfer device may include a single hexapole that extends over the entire length of the ion transfer device. Also possible are multiple hexapoles arranged in succession in the longitudinal direction.

A DC bias matched to the electric potential at the outlet end of the ion decelerator may be applied to the pole arrangement. In this way, the ionized constituents maintain their preferred axial direction when passing through the ion transfer device. In addition to, or in an alternative, the ion transfer device may also be provided with an ion funnel, i.e., equipment for focusing an ion beam using a number of successively arranged ring electrodes of decreasing internal diameter.

There may be free gas exchange between the interior of the ion transfer device and the vacuum environment from which the residual gas is taken, and so the residual gas atmosphere in the ion transfer device is similar to that of the vacuum environment. In that case and on account of collisions with other constituents, especially hydrogen constituents of the residual gas, the ionized constituents of the residual gas are decelerated during their passage through the ion transfer device. Should the path to be traveled within the ion transfer device be sufficiently long, the ionized constituents are decelerated to such an extent that all excess kinetic energy still present upon departure from the ion decelerator is consumed, and the ionized constituents are reduced to their thermal energy. This is advantageous because the ionized constituents thus have a defined state on entry into the mass spectrometer. It is advantageous if the ion transfer device extends over a distance of at least 20 cm, preferably at least 50 cm, further preferably at least 80 cm.

The mass spectrometer may also take the form of a time-of-flight mass analyzer (TOF analyzer), especially of a time-of-flight mass analyzer with an orthogonal acceleration stage. The mass spectrometer may encompass a measurement range of 1 to 500 daltons, preferably 1 to 1000 daltons, such that complete mass spectra can be recorded over this mass range. The recording frequency of the mass spectrometer may be greater than 10 kHz. An improvement in the signal-to-noise ratio can be achieved by adding up a plurality of the spectra recorded with the mass spectrometer. The time resolution of the overall system emerges from the frequency with which the spectra are transferred to the evaluation. This frequency may be between 0.1 Hz and 100 Hz. This is a distinct improvement over existing systems in which several minutes are required for recording of a single spectrum over the measurement range of 1 to 200 daltons.

The residual gas analyzer may include a filter device (or filter) in order to filter out ionized constituents having a particular mass/charge ratio. The filter device can filter ionized constituents still present upon emergence from the ion decelerator out of the ion stream, such that they cannot make any contribution to the mass spectrometry analysis. In particular, constituents that are ionized with the filter device and are present in high density in the ion stream may be filtered out in order to thus increase the dynamic range of the mass spectrometer. Constituents that are frequently present in high concentration in the residual gas are, for example, hydrogen (H₂) or nitrogen (N₂).

The filter device may take the form of a quadrupole. By applying a suitable alternating field, the quadrupole can be set such that specific constituents of the residual gas are filtered out and consequently make no contribution to the mass spectrometry analysis. The filter device may be arranged between the ion transfer device and the mass spectrometer. The filter device may be connected to the mass spectrometer to form a common component.

A switchable ion source may be arranged between the ion decelerator and the mass spectrometer. In a first switching state, the switchable ion source may act as ion optics, via which the ion stream is guided to the mass spectrometer. The ion source may include an ionization unit (or ionizer) which is designed to ionize neutral constituents of the residual gas. The ionization unit may be inactive in the first switching state of the ion source, and so the ion stream coming from the ion decelerator can pass through the ion source without being influenced by the ionization unit. The ionization unit may be active in a second switching state. In this switching state, the residual gas analyzer may be utilized to analyze neutral constituents of the residual gas that have arrived at the switchable ion source from the vacuum environment via free gas exchange. The switchable ion source may be arranged between the ion transfer device and the mass spectrometer. The switching time for the switching between the first switching state and the second switching state may be less than 1 s, and so a change between the two modes of operation of the residual gas analyzer is possible at short notice at any time.

The result of the mass spectrometry analysis is independent of the excess kinetic energy of the ionized constituents upon departure from the ion decelerator. The result of the mass spectrometry analysis corresponds in each case to the sum of ions whose kinetic energy on entry into the ion decelerator was above a certain threshold value.

Performing the mass analysis multiple times with different values for the deceleration voltage of the ion decelerator allows the ionized constituents to be analyzed for different threshold values of the initial kinetic energy. Subtracting the summed values allows determination of a mass spectrum associated with a specific interval of kinetic energy.

The residual gas analyzer may include a control unit (or controller) designed to control the component parts of the residual gas analyzer. The control unit may direct control commands, which set the deceleration voltage of the ion decelerator to different values, to the ion decelerator. The control unit may be designed to store a mass spectrum ascertained with the mass analyzer in a memory unit (or memory) such that assignment between the measured mass spectrum and the corresponding deceleration voltage of the ion decelerator is assured. The control unit may further be designed to form the difference between a first mass distribution ascertained at a first deceleration voltage and a second mass distribution ascertained at a second, higher deceleration voltage in order to obtain a mass distribution of those ions whose kinetic energy at the inlet of the ion decelerator was sufficient to overcome the first deceleration voltage and whose kinetic energy at the inlet of the ion decelerator was not sufficient to overcome the second deceleration voltage.

It was found that the kinetic energy of the ions relevant to the degradation effects is between 1 eV and 50 eV. Ions with a kinetic energy of between 5 eV and 20 eV are of particular interest. The deceleration voltage of the ion decelerator may be set such that the spectra recorded at the voltages yields differentiation within this energy range. For example, the deceleration voltage may be set to at least three values between 5 V and 20 V, preferably to at least five values and further preferably to at least ten values. A mass spectrometry analysis can be performed at each of the values for the deceleration voltage.

The disclosed techniques also relate to a microlithography projection exposure apparatus equipped with such a residual gas analyzer. The projection exposure apparatus may include a radiation source that emits very short-wave UV radiation. Very short-wave UV radiation includes DUV radiation in the deep ultraviolet spectral range with wavelengths between 100 nm and 300 nm and EUV radiation in the extreme ultraviolet spectral range with wavelengths between 5 nm and 100 nm, especially with wavelengths between 5 nm and 30 nm. The projection exposure apparatus may include an exposure system and a projection lens, wherein the exposure system directs the very short-wave UV radiation onto an object field in an object plane, and wherein the projection lens images the object field into an image plane. The projection exposure apparatus may include a plurality of optical elements with which the very short-wave UV radiation is directed along an exposure beam path to the image plane. The optical elements may take the form of reflective optical elements.

The optical component parts of the projection exposure apparatus may be enclosed in a vacuum housing. The projection exposure apparatus may include a vacuum pump connected to the vacuum housing, which is designed to generate a high vacuum in the vacuum housing. The pressure of the high vacuum may, for example, be between 10⁻⁷ and 10⁻⁸ mbar.

An inner housing may be formed within the vacuum housing. The inner housing may wholly or partly enclose sections of the exposure beam path and/or one or more optical elements, such that a micro-environment is formed within the vacuum housing. The inner housing need not be impervious in a macroscopic sense. Under high vacuum conditions in the vacuum housing, an inner housing which is not impervious in a macroscopic sense may be sufficient to create a distinctly different atmosphere within the micro-environment than in the rest of the vacuum housing.

The inner housing may be provided with a connection for a purge gas, such that an atmosphere different from the rest of the vacuum housing can be applied in the micro-environment. The pressure in the micro-environment may be in the fine vacuum region, for example between 10⁻¹ mbar and 10⁻³ mbar. The purge gas may be hydrogen (H₂), which serves to remove contamination from the micro-environment and especially from the mirror surfaces present therein. The atmosphere in the inner housing may be formed by the residual gas which is examined by the residual gas analyzer according to the disclosed techniques.

An inlet opening for the residual gas analyzer may be arranged in the inner housing. In particular, the inlet end of the ion decelerator may be connected to the inner housing of the projection exposure apparatus such that the residual gas from the micro-environment can enter the ion decelerator. The mass spectrometer may be arranged outside the vacuum housing. Should the residual gas analyzer include a switchable ion source, the latter may also be arranged outside of the vacuum housing. The path taken by the ions between the micro-environment and the mass spectrometer may extend within a vacuum tube. A vacuum tube refers to a housing wall that separates an interior enclosed by the housing wall from the atmosphere in the vacuum housing. The term “vacuum tube” does not imply any restriction to a particular structure or shape of the housing wall. Free mass transfer may exist between the interior of the vacuum tube and the micro-environment, such that the atmosphere in the vacuum tube corresponds essentially to the atmosphere in the micro-environment.

The predominant portion of the distance between the wall of the inner housing and the wall of the vacuum housing may be occupied by the ion transfer device. For example, the ion transfer device may extend over at least 50% of this distance, preferably over at least 70% and further preferably over at least 90%. In that case, a sufficient amount of distance is available so that the ions that have passed through the ion decelerator can be thermalized by collisions with constituents of the residual gas. The deceleration path of the ion decelerator preferably makes up less than 20% of the distance between the inlet opening for the residual gas analyzer and the inlet opening for the mass spectrometer, further preferably less than 10% and further preferably less than 5%.

The disclosed techniques also relate to a method of residual gas analysis, especially for a residual gas in a microlithography projection exposure apparatus. In the method, ionized constituents of the residual gas are guided from a vacuum environment into a mass spectrometer. An ion decelerator is arranged between the vacuum environment and the mass spectrometer in order to decelerate the ionized constituents using an adjustable deceleration voltage. Mass spectra are recorded for different values of the deceleration voltage.

This disclosure encompasses developments of the method with features that are described in the context of the residual gas analyzer according to the disclosed techniques. The disclosure encompasses developments of the residual gas analyzer with features that are described in the context of the method according to the disclosed techniques.

### BRIEF DESCRIPTION OF THE DRAWINGS

The disclosed techniques are described by way of example hereinafter using advantageous embodiments, with reference to the appended drawings. In the figures:

FIG. 1: shows an embodiment of a projection exposure apparatus according to the disclosed techniques;

FIG. 2: an embodiment of a residual gas analyzer according to the disclosed techniques;

FIG. 3: the ion decelerator from FIG. 2 in an enlarged illustration;

FIG. 4: a mass spectrum recorded with a residual gas analyzer according to the disclosed techniques;

FIG. 5: a mass spectrum recorded without a low-mass filter;

FIG. 6: a mass spectrum recorded with a low-mass filter.

### DETAILED DESCRIPTION

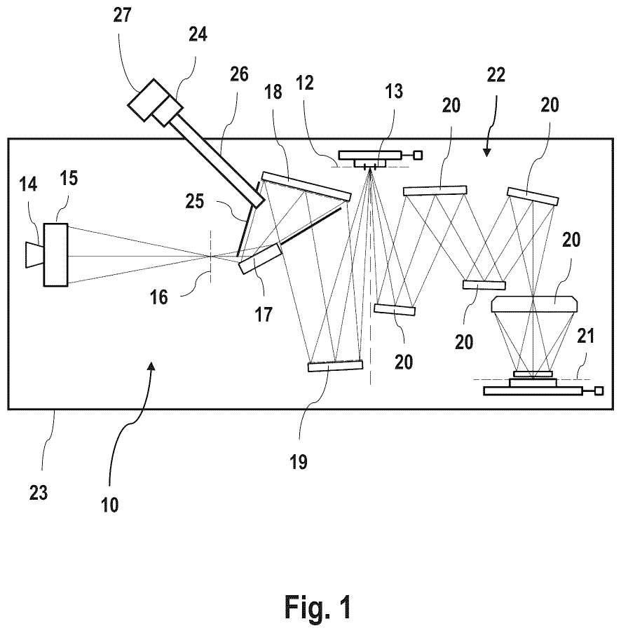

FIG. 1 shows a schematic of a microlithography EUV projection exposure apparatus. The projection exposure apparatus includes an exposure system 10 and a projection lens 22. The exposure system 10 exposes an object field 13 in an object plane 12. The projection lens 22 serves to image the object field 13 into an image plane 21.

The exposure system 10 includes an exposure radiation source 14 which emits electromagnetic radiation in the EUV range, i.e., with a wavelength of between 5 nm and 30 nm in particular. The EUV radiation emanating from the exposure radiation source 14 is first focused into an intermediate focus plane 16 with a collector 15.

A deflecting mirror 17 deflects the EUV radiation onto a first facet mirror 18. The first facet mirror 18 is followed by a second facet mirror 19, with which the individual facets of the first facet mirror 18 are imaged into the object field 13.

With the aid of the projection lens 22, the object field 13 is imaged into an image plane 21 using a plurality of mirrors 20. Arranged in the object field 13 is a mask (also called a reticle) which is imaged onto a light-sensitive layer of a wafer arranged in the image plane 21.

The various mirrors of the projection exposure apparatus at which the illumination radiation is reflected take the form of EUV mirrors. The EUV mirrors have been provided with highly reflective coatings. These may be multilayer coatings, especially multilayer coatings having alternating layers of molybdenum and silicon.

The component parts of the projection exposure apparatus are arranged in a vacuum housing 23. The interior of the vacuum housing 23, in operation of the projection exposure apparatus, is put under high vacuum with a vacuum pump (not shown) at a pressure of, for example, 10⁻⁸ mbar. Formed in the interior of the vacuum housing 23 is an inner housing 25 that surrounds the exposure beam path.

FIG. 1 indicates merely a section of the inner housing 25 arranged between the deflecting mirror 17 and the first facet mirror 18. In fact, the inner housing 25 surrounds further sections of the beam path. The inner housing 25 is configured such that the exposure beam path can travel via various optical elements 17, 18, 19, 20, without the inner housing 25 being in the way.

The inner housing 25 is not impervious in the macroscopic sense with respect to the remainder of the interior of the vacuum housing 23. For example, gaps that may be formed between the inner housing 25 and optical elements 17, 18, 19, 20, at which the exposure beam path is reflected, permit mechanical adjustment of the optical elements. Nevertheless, the inner housing 25, under the high-vacuum conditions that exist in the vacuum housing 23, enables an atmosphere in the interior of the inner housing 25 which is distinctly different from the atmosphere in the rest of the vacuum housing 23.

The projection exposure apparatus includes a purge gas connection (not shown in FIG. 1) via which hydrogen is fed into the inner housing 25, such that there is a partial hydrogen pressure in the order of 10⁻² mbar in the interior of the inner housing 25.

Interaction between the EUV radiation and the hydrogen creates a plasma, forming ionic plasma species (H⁺) or free-radical plasma species (H), inter alia. The hydrogen plasma has the effect that contamination is removed from surfaces of the optical elements arranged in the inner housing 25. This gives rise to compounds, for example, of hydrogen and carbon or of hydrogen and nitrogen that are distributed in the residual gas atmosphere in the interior of the inner housing 25.

The residual gas analyzer 24 according to the disclosed techniques has the purpose of obtaining information about the composition of the residual gas in the interior of the inner housing 25. Ionic species contained in the residual gas atmosphere are of particular interest. Going beyond the type of species, the residual gas analyzer according to the disclosed techniques allows ascertainment of the distribution of kinetic energy in the species. FIG. 1 shows a single residual gas analyzer 24 connected to the inner housing 25 in the region between the deflecting mirror 17 and the first facet mirror 18. The projection exposure apparatus may include a plurality of residual gas analyzers 24 in order to be able to analyze the composition of the residual gas in various regions of the inner housing 25.

The residual gas analyzer 24 includes a vacuum tube 26 that extends outward from the interior of the inner housing 25 through the wall of the vacuum housing 23. The length of the vacuum tube 26 is on the order of 80 cm. The vacuum tube 26 has an inlet opening arranged in the inner housing 25, such that exchange of gas takes place between the residual gas atmosphere in the inner housing 25 and the interior of the vacuum tube 26. The vacuum tube 26 is sealed with respect to the interior of the vacuum housing 23.

The ionic species are guided through the vacuum tube 26 to a mass spectrometer 27 arranged outside the vacuum housing 23, where they are analyzed for their mass-to-charge ratio.

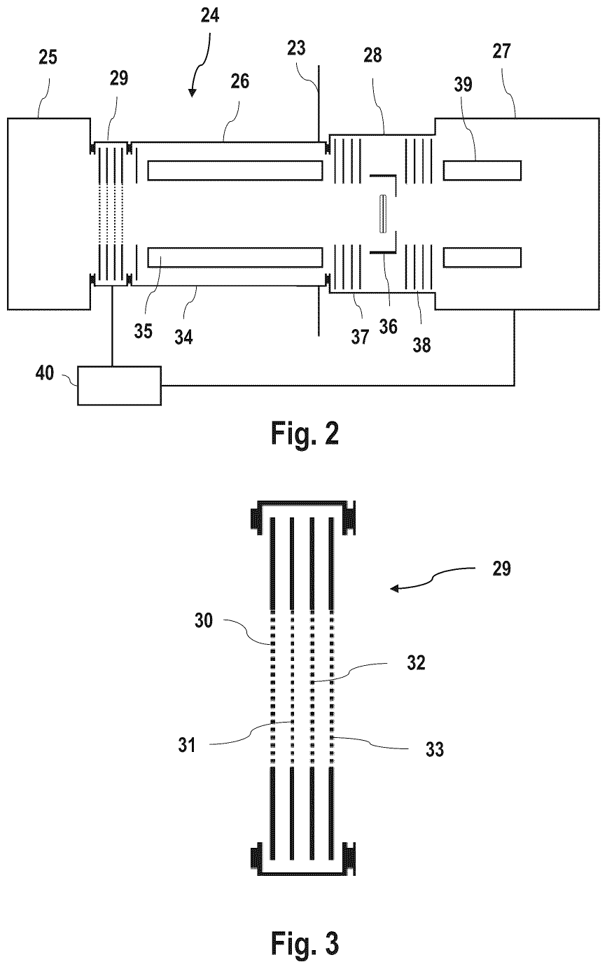

According to FIG. 2, the residual gas analyzer 24, within the vacuum tube 26, includes an ion decelerator 29 and an ion transfer device 34. Outside the vacuum housing 23 are arranged a switchable ion source 28 and a mass spectrometer 27.

The ion decelerator 29 is arranged adjacent to the inlet opening of the vacuum tube 26, and so ionic species that pass into the vacuum tube 26 go in high number into the region of influence of the ion decelerator 29, without being neutralized beforehand by contact with other component parts of the residual gas analyzer 24.

The ion decelerator 29, according to FIG. 3, includes four grids 30, 31, 32, 33, arranged successively in the direction of movement of the ionic species. The first grid 30 is grounded, and so the electric potential corresponds to that of the wall of the inner housing 25. A negative potential is applied to the second grid 31, and so electrons are removed from the residual gas while the ionic species are able to pass through the second grid 31. A positive potential, the magnitude of which is adjustable, is applied to the third grid 32. The positive potential at the third grid 32 defines the deceleration voltage to which the ionic species are exposed when passing through the ion decelerator 29. The higher the positive potential at the third grid 31, the more ionic species provided with a positive charge are decelerated. Only ionic species with sufficient kinetic energy to overcome the deceleration voltage advance to the outlet end of the ion decelerator 29. The fourth grid 33 is at a negative potential again and acts as a secondary electron trap.

The ion decelerator 29 has a length of a few centimeters, and so a considerable distance within the vacuum tube 26 still has to be covered before the composition of the ionic species can be examined by the mass spectrometer 27. The ion species are guided onward through the vacuum tube 26 by the ion transfer device 34. The ion transfer device 34 includes a hexapole 35 that extends in the direction of movement of the ions. The hexapole 35 is formed by six poles distributed uniformly over the circumference of the ion transfer device 34, which are alternately at a positive or negative potential. In addition to an AC voltage applied to the hexapole 35, it is also possible to apply a DC bias, the magnitude of which is such that the ionic species retain their preferential direction. The hexapole 35 acts as ion optics, with which the ionic species are concentrated to an ion beam that moves along the central axis of the hexapole 35. FIG. 2 shows a single hexapole 35 that extends over the entire length of the ion transfer device 34. In an alternative, multiple hexapoles 35 may be arranged successively in longitudinal direction of the ion transfer device 34.

Since uncharged species can pass through the ion decelerator 29 unhindered, there is an atmosphere with a high proportion of hydrogen in the region of the ion transfer device 34, similarly to that in the inner housing 25. Collisions with the hydrogen constituents result in deceleration of the ionic species, such that the kinetic energy of the ionic species corresponds essentially to thermal movement at the outlet from the ion transfer device 34. This means that the ionic species at the outlet from the ion transfer device 34 have a defined state, which creates a favorable starting point for the subsequent mass spectrometry analysis.

In the exemplary embodiment as per FIG. 2, a switchable ion source 28 adjoins the end of the vacuum tube 26. The switchable ion source 28 is arranged outside of the vacuum housing 23. In a first switching state, the switchable ion source 28 acts as ion optics, with which the ions passing across from the ion transfer device 34 are focused on the inlet of the mass spectrometer 27. The ion optics are formed by a first electrode arrangement 37 and a second electrode arrangement 38, which are suitably controlled by electrical signals.

The ion source 28 further includes an ionization unit 36 which is designed to ionize neutral constituents of the residual gas. In the first switching state of the ion source 28, the ionization unit 36 is inactive, such that the ions coming from the ion transfer device 34 can pass through the ion source 28 unaffected by ionization unit 36.

The ionization unit 36 is active in a second switching state. In this switching state, the residual gas analyzer 24 is utilized in order to analyze neutral constituents of the residual gas that have arrived at the switchable ion source 28 from the inner housing 25 via free gas exchange. The ion decelerator 29 and the ion transfer device 34 play no role when the ion source 28 is in the second switching state. The switching time for the switching between the first switching state and the second switching state is less than 1 s, such that a change between the two modes of operation of the residual gas analyzer is possible at short notice at any time.

The mass spectrometer 27 may also take the form of a time-of-flight mass analyzer (TOF analyzer), especially of a time-of-flight mass analyzer with an orthogonal acceleration stage. The mass spectrometer 27 may have a measurement range of 1 to 500 daltons, such that complete mass spectra can be recorded over this mass range. The recording frequency of the mass spectrometer may be greater than 10 kHz. Addition of the spectra can achieve a distinct improvement in the signal-to-noise ratio.

The time resolution of the overall system emerges from the frequency with which the spectra are transferred to the evaluation. This frequency may be between 0.1 Hz and 100 Hz. This is a distinct improvement over existing systems in which several minutes are required for recording of a single spectrum over the measurement range of 1 to 200 daltons.

The inlet of the mass spectrometer 27 is formed by a quadrupole 39. The quadrupole 39 can filter out ions that enter the mass spectrometer 27 in high density, in order thus to increase the dynamic range of the mass spectrometer. In particular, it is possible to specifically filter individual constituents of the residual gas that have a particular mass-to-charge ratio, for example the hydrogen (H₂) or nitrogen (N₂) constituents that are frequently present with a high partial pressure. By applying a suitable AC field, the quadrupole 39 can be set such that particular constituents of the residual gas are filtered out and consequently make no contribution to the mass spectrometry analysis.

The residual gas analyzer 24 includes a control unit (or controller) 40 that controls the interplay of the component parts of the residual gas analyzer 24. The control unit 40 transmits control commands to the ion decelerator 29 in order to set the ion decelerator 29 to a specific deceleration voltage. The control unit 40 stores the mass spectra obtained with the mass spectrometer 27 in such a way that there is assignment between the mass spectra and the respective associated deceleration voltage.

The analysis can be performed in such a way that, in a first step, a voltage of 0 eV is applied to the third grid 32 of the ion decelerator 29 such that the ionic species can pass out of the inner housing 25 and through the ion decelerator 29 in unimpeded fashion, independently of their kinetic energy. The associated mass spectrum captures all ionic species, independently of the magnitude of their kinetic energy on entry into the ion decelerator 29. A positive voltage of 1 V can be applied to the third grid 32 in a subsequent step, and so the ion decelerator 29 is passed only by those ionic species whose kinetic energy on entry into the ion decelerator 29 was so high that the deceleration voltage was overcome. The difference from the two mass spectra corresponds to the number of ions with a kinetic energy of between 0 eV and 1 eV. This method can be performed up to 50 eV with appropriate gradation, and so an analysis of the composition of the ionic species is obtained in 50 different classes, with each class corresponding to a specific range of the kinetic energy on entry into the ion decelerator 29. The region of 5 eV and 20 eV is of particular interest.

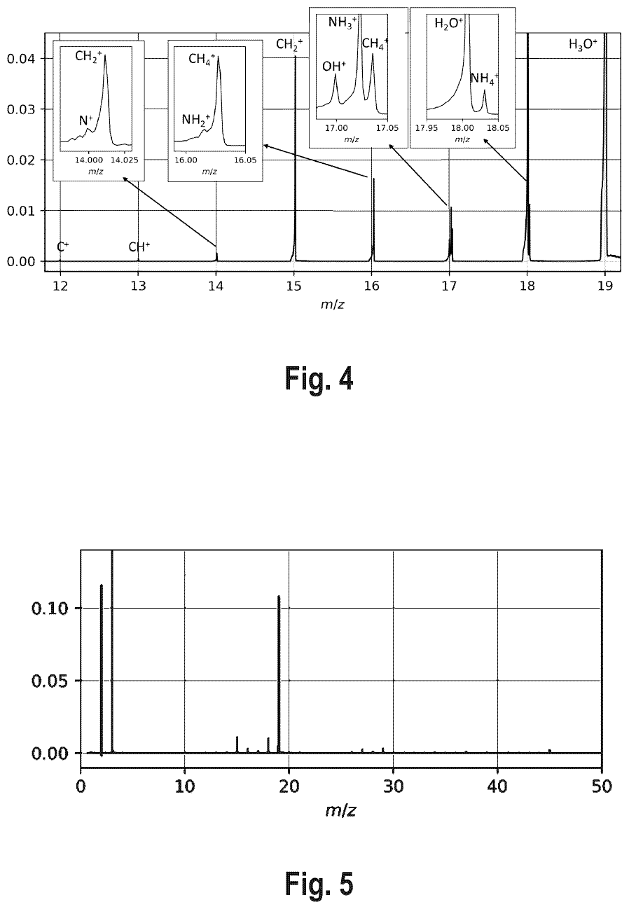

FIG. 4 depicts a single mass spectrum of this type, which was generated with a mid-range deceleration voltage. Plotted on the horizontal axis is the mass-to-charge ratio m/z, and on the vertical axis the intensity in normalized units. What is shown is the very good resolution that can be achieved with the residual gas analyzer according to the disclosed techniques because of the defined state of the ionic species on entry into the mass spectrometer 27. For instance, at about 17 daltons, the ionic species OH⁺, NH₃⁺ and CH₄⁺ form three distinctly separated peaks. The same applies to the peaks of H₂O⁺ and NH₄⁺ close to 18 daltons. In conventional methods, these peaks vanish within a broader distribution.

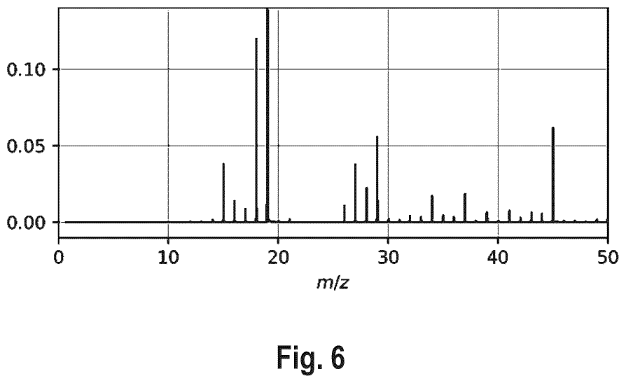

FIG. 5 shows a corresponding mass spectrum which is saturated at 3 daltons (H₃⁺). The mass spectrum was recorded with an RF voltage of 21 V at the quadrupole 39, a consequence of which is that the H₃₊ species pass through the quadrupole filter in a large number. For comparison, FIG. 6 shows a mass spectrum in which there is an RF voltage of 230 V at the quadrupole 39, as a result of which the H₃⁺ species are effectively filtered out, such that they play no role in respect of the mass spectrometry analysis. The signal is now saturated at 19 daltons (H₃O⁺), which results in a significant increase in the dynamic range of analysis.

What is claimed is:

1. A projection exposure apparatus comprising:
a vacuum housing;
a radiation source for emitting very short-wave UV radiation arranged within the vacuum housing;
a plurality of optical elements configured to guide radiation emitted along an exposure beam path of the projection exposure apparatus into an image plane; and
a residual gas analyzer configured to analyze a residual gas in the projection exposure apparatus, the residual gas analyzer comprising:
a mass spectrometer; and
admission equipment configured to admit ionized constituents of the residual gas into the mass spectrometer from a vacuum environment, the admission equipment comprising an ion decelerator configured to provide an adjustable deceleration voltage to subject the ionized constituents to a selection according to kinetic energy prior to transfer into the mass spectrometer.

2. The projection exposure apparatus of claim 1, wherein the ion decelerator comprises a deceleration path extending between an inlet end and an outlet end of the ion decelerator, and wherein an electric potential at the inlet end corresponds to an electric potential of a housing of the vacuum environment.

3. The projection exposure apparatus of claim 1, wherein the ion decelerator comprises a plurality of grids through which the ionized constituents pass, and wherein a deceleration voltage is applied across the plurality of grids.

4. The projection exposure apparatus of claim 1, wherein the admission equipment comprises an ion transfer device arranged between the ion decelerator and the mass spectrometer.

5. The projection exposure apparatus of claim 4, wherein the ion transfer device comprises a pole arrangement acting as ion optics.

6. The projection exposure apparatus of claim 4, wherein the ion transfer device extends over a distance of at least 20 cm.

7. The projection exposure apparatus of claim 6, wherein the ion transfer device extends over a distance of at least 50 cm.

8. The projection exposure apparatus of claim 7, wherein the ion transfer device extends over a distance of at least 80 cm.

9. The projection exposure apparatus of claim 1, wherein the mass spectrometer comprises a time-of-flight mass analyzer.

10. The projection exposure apparatus of claim 1, further comprising a filter arranged between the ion decelerator and the mass spectrometer configured to filter out ionized constituents present in high density.

11. The projection exposure apparatus of claim 10, wherein the filter comprises a quadrupole to which an alternating electric field is applied.

12. The projection exposure apparatus of claim 1, further comprising a controller configured to control the ion decelerator such that the ion decelerator is set to different deceleration voltages.

13. The projection exposure apparatus of claim 12, wherein a deceleration voltage of the different deceleration voltages is set to a values between 5 V and 20 V.

14. The projection exposure apparatus of claim 1, further comprising an inner housing formed within the vacuum housing, wherein an atmosphere in the inner housing differs from an atmosphere in a remainder of the vacuum housing, and wherein an inlet opening of the residual gas analyzer is arranged in the inner housing.

15. A method of residual gas analysis for a residual gas in a microlithographic projection exposure apparatus comprising:
guiding ionized constituents in the residual gas from a vacuum environment into a mass spectrometer;
decelerating the ionized constituents with an ion decelerator arranged between the vacuum environment and the mass spectrometer using an adjustable deceleration voltage such that the ionized constituents are subjected to a selection according to kinetic energy prior to transfer into the mass spectrometer; and
recording mass spectra for different values of the adjustable deceleration voltage.

16. The method of claim 15, wherein the microlithographic projection exposure apparatus comprises a vacuum housing; and
wherein guiding the ionized constituents in the residual gas from the vacuum environment comprises guiding the residual gas from the vacuum housing.

17. The method of claim 16, wherein the vacuum housing comprises an inner housing in which one or more optical elements of the microlithographic projection exposure apparatus are arranged; and
wherein guiding the ionized constituents in the residual gas from the vacuum environment comprises guiding the residual gas from the inner housing.
